(19) United States
(12) Patent Application Publication
(10) Pub. No.: US 2016/0373122 A1
(43) Pub. Date: Dec. 22, 2016

(54) FREQUENCY SYNTHESIZER CIRCUIT

(71) Applicant: NXP B.V.

(72) Inventors: Tarik Saric, Eindhoven (NL); Juan Felipe Osorio Tamayo, Eindhoven (NL)

(21) Appl. No.: 15/170,624

(22) Filed: Jun. 1, 2016

(30) Foreign Application Priority Data
Jun. 18, 2015 (EP) 15172783.1

(51) Int. Cl. H03L 7/107; H03L 7/197; H03L 7/093; H03L 7/089

(52) U.S. Cl. CPC H03L 7/107; H03L 7/0891; H03L 7/1974; H03L 7/093

(57) ABSTRACT

A frequency synthesizer circuit for a car radar system is disclosed, the circuit comprising: a phase locked loop for providing a frequency chirp at a range of tuning voltages, said phase locked loop comprising: a phase detector and a voltage controlled oscillator, wherein said phase locked loop has an open loop gain dependent on the tuning voltage and a gain of the voltage controlled oscillator; a first varactor unit for altering the gain of the voltage controlled oscillator over a first subset range of tuning voltages; and a second varactor unit for altering the gain of the voltage controlled oscillator over a second subset range of tuning voltages, wherein the second subset range of tuning voltages is higher than the first subset range of tuning voltages; such that variations in the open loop gain over the first and second subset range of tuning voltages of the range of tuning voltages are compensated for by the varactor units.

The present disclosure relates to a frequency synthesizer circuit for a radar system. In particular, the present disclosure relates to the use of varactors to compensate for variations in the open loop gain of such circuits.

Various example embodiments of systems, methods, apparatuses, devices, articles of manufacture and computer readable mediums for frequency synthesizer circuits are now discussed. Phase locked loops (known as PLLs) are control systems (frequency synthesiser circuits) used to generate output signals. A phase locked loop generates an output signal with a phase related to the phase of a highly accurate input signal (reference signal). A PLL is typically used to ensure that the clock frequencies of signal inputs of various registers and flip-flops match the frequency generated by an oscillator. Without a PLL, clock skew may result in the registers and flip-flops not receiving the clock at the same time.

Traditional analogue PLLs utilise a voltage controlled oscillator (VCO) to provide an oscillating waveform with a variable frequency. The output of the VCO is compared to a reference input signal by a phase detector, which compares the phase of the input and output signals and adjusts the oscillator to keep the phases matched. This acts as a feedback loop.

The frequency of the output may be varied by introducing a divider that allows the output frequency to be a multiplied copy of the lower reference frequency, which is usually insensitive to process voltage and temperature variations. However, this provides the constraint that the oscillator frequency is equal to an integer multiple of the reference frequency. Such analogue circuits are called integer-N frequency synthesisers.

This limitation may be overcome by introducing a modulator or dither to divide the value of the divider to achieve fractional divide values. The resulting variations are smoothed by the PLL using a loop filter. Such analogue PLL's are called fractional-N frequency synthesisers.

The gain of the phase lock loop is a design parameter that is used to optimize the bandwidth, locking time and noise performance of the PLL. For example, both the charge pump gain, K_{D} (PFD/CP gain) and the oscillator gain, Kvco (VCO gain) are parameters that are ideally linear. This is broadly the case in traditional PLLs for the charge pump gain, but for the voltage controlled oscillator gain the gain is typically peaked due to the electrical response of the varactor used to tune the PLL.

The gain of the voltage controlled oscillator operates in this narrow window due to the peak gain response. This is in most applications acceptable since the PLL is locked to one frequency that corresponds to a mid-tune voltage. In systems where the tuned voltage is changing in time, for example to generate frequency chirp, this decrease in Kvco leads to a phase noise variation and linearity variation of this frequency chirp. This is unsuitable in some applications, such as in sensors for car radar systems. In such systems, a frequency synthesiser circuit with a more constant gain profile over the tuning voltage is desirable.

### SUMMARY

According to a first aspect of the present disclosure, there is provided a frequency synthesiser circuit for a radar system, the circuit comprising: a phase locked loop for providing a frequency chirp at a range of tuning voltages, said phase locked loop comprising: a phase detector, and a voltage controlled oscillator, wherein said phase locked loop has an open loop gain dependent on the tuning voltage and the gain of the voltage controlled oscillator; a first varactor unit for altering the gain of the voltage controlled oscillator over a first subset range of tuning voltages; and a second varactor unit for altering the gain of the voltage controlled oscillator over a second subset range of tuning voltages wherein the second subset range of tuning voltages is higher than the first subset range of tuning voltages, such that variations in the open loop gain over the first and second subset range of tuning voltages of the range of tuning voltages are compensated for by the varactor units.

The gain of the voltage controlled oscillator is at least partly determined by the varactor units. Accordingly, by altering the characteristics and/or number of varactor units and/or the bias voltages supplied to the varactor units, the gain of the voltage controlled oscillator can be controlled.

Consequently, the varactor units within the voltage controlled oscillator act to alter the gain of the voltage controlled oscillator, which in turn alters the frequency response of the voltage controlled oscillator with respect to the range of tuning voltages supplied to the voltage controlled oscillator. Variations in the supplied frequency response of the voltage controlled oscillator at different applied tuning voltages are therefore reduced.

In embodiments, a charge pump may be provided to supply the tuning voltage either directly or via a loop filter. The charge pump may have a gain that contributes to the overall open loop gain of the phase locked loop.

In other embodiments, a divider may be provided for varying the frequency output at a tuning voltage.

In embodiments, the varactor units may be scaled or sized to alter the voltage controlled oscillator gain that is higher at low and high tuning voltages to compensate for drop-off in the gain of the charge pump. This allows the overall open loop gain of the phase locked loop to remain substantially constant.

By altering the gain of the voltage controlled oscillator, the response of the open loop gain across the sweeping tuning voltage can be flattened, reducing variations across different voltage ranges.

In embodiments, the circuit further comprises a third varactor unit for altering the gain of the voltage controlled oscillator over a third subset range of tuning voltages. In such examples, the third subset range of tuning voltages are generally lower than the second subset range of tuning voltages and higher than the first subset range of tuning voltages. Furthermore, the third varactor may alter the gain of the voltage controlled oscillator by a lower amount than the first or second varactor.

This may be further generalised to an nth varactor unit for altering the gain of the voltage controlled oscillator over an nth subset range of tuning voltages of the range of tuning voltages. It can be appreciated that more of less varactor units may be employed within the voltage controlled oscillator depending upon the required application. Additionally, although shown as pairs of varactors, each varactor unit may be a single varactor biased by a single bias voltage, a triplet of varactors each biased by a single bias voltage, or 4 or more varactors each biased by a single bias voltage. However, as the number of varactor units used increases, the reactance of the circuit increases as well as parasitic which can lead to increased phase noise, so a tradeoff is necessary.

Typically each varactor unit may comprise a pair of varactors biased by a bias voltage. The bias voltage may be generated by a current and a low pass filter. Low pass filters may be used to lower in-band noise.

The amount of compensation in the open loop gain by the varactor units may be dependent upon the size of the varactor unit, such as the capacitance of the varactor unit, and the bias voltage of the varactor unit. This allows the varactor unit to be tailored to compensate over the desired range of the sweeping tuning voltage. For example, the varactor units may compensate for variations in the open loop gain at high and low sweeping tune voltages.

In embodiments, the varactor units contain diodes. Alternatively or additionally, the varactor units may contain capacitors.

In examples, the frequency chirp generated by the phase locked loop relates to a distance measurement for use in a radar system. In such scenarios a stable gain of the voltage controlled oscillator and therefore the open loop gain of the circuit is particular useful in such applications.

In other examples, a divider is provided and implemented with a sigma-delta to obtain a fractional-N phase locked loop. This can allow a greater control of the frequency chirp generated by the phase locked loop. In embodiments, the frequency chirp of the phase locked loop may be generated by changing a division ratio of a divider. Alternatively, or additionally, the frequency chirp of the phase locked loop may be generated by changing an input reference frequency signal.

In a second aspect of the present disclosure, there is provided a sensor for determining a distance between objects, said sensor comprising a circuit according to any example of the first aspect.

There may be provided a computer program, which when run on a computer, causes the computer to configure any apparatus, including a circuit, controller, sensor, filter, or device disclosed herein or perform any method disclosed herein. The computer program may be a software implementation, and the computer may be considered as any appropriate hardware, including a digital signal processor, a microcontroller, and an implementation in read only memory (ROM), erasable programmable read only memory (EPROM) or electronically erasable programmable read only memory (EEPROM), flash memory, or a chip as non-limiting examples. The software implementation may be an assembly program.

The computer program may be provided on a computer readable medium, which may be a physical computer readable medium, such as a disc or a memory device, or may be embodied as a transient signal. Such a transient signal may be a network download, including an internet download.

The above discussion is not intended to represent every example embodiment or every implementation within the scope of the current or future Claim sets. The Figures and Detailed Description that follow also exemplify various example embodiments. Various example embodiments may be more completely understood in consideration of the following Detailed Description in connection with the accompanying Drawings.

### BRIEF DESCRIPTION OF DRAWINGS

Embodiments will be described, by way of example only, with reference to the drawings, in which

FIG. 1A shows a typical phase locked loop architecture with a voltage controlled oscillator;

FIG. 1B shows a typical gain for the phase frequency detector of FIG. 1A;

FIG. 1C shows a typical gain for the voltage controlled oscillator of FIG. 1A;

FIG. 2A shows a typical response of the tuning voltage supplied by the architecture of FIG. 1 as the frequency of the architecture of FIG. 1A varies over time, for different gains of the voltage controlled oscillator;

FIG. 2B shows the variation of the frequency of the voltage controlled oscillator over the time corresponding to FIG. 2A;

FIG. 3A shows a frequency response of varactor units over a swept tuning voltage range according to an example embodiment of the present disclosure;

FIG. 3B shows the derivative of the varactor units frequency response shown in FIG. 3A;

FIG. 3C shows the Charge-Pump gain across the swept tuning voltage range using the varactor units of FIG. 3A;

FIG. 3D shows the voltage controlled oscillator gain across the swept tuning voltage range using the varactor units of FIG. 3A;

FIG. 4 shows a circuit implementation with an arrangement of varactors according to an example embodiment of the present disclosure.

It should be noted that the Figures are diagrammatic and not drawn to scale. Relative dimensions and proportions of parts of these Figures have been shown exaggerated or reduced in size, for the sake of clarity and convenience in the drawings. The same reference signs are generally used to refer to corresponding or similar feature in modified and different embodiments.

### DETAILED DESCRIPTION OF EMBODIMENTS

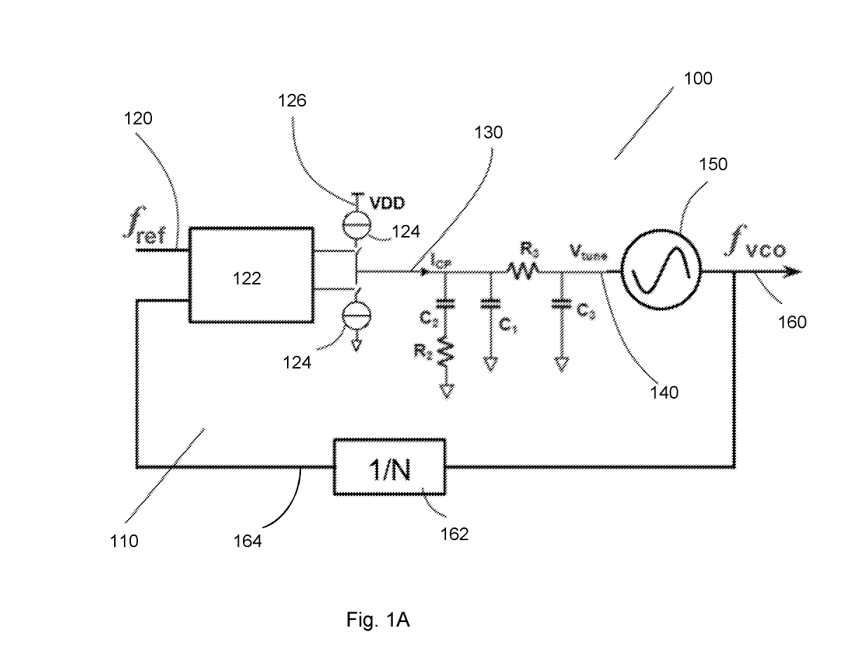

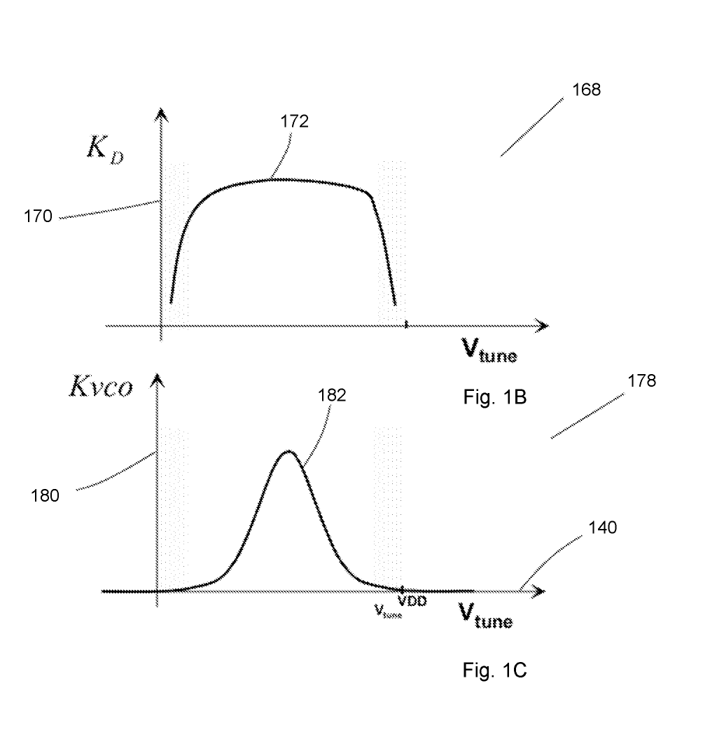

An example of a frequency synthesiser circuit, known as a Phase Locked Loop (PLL) is shown in FIG. 1A. The phase locked loop 110 comprises a Phase Detector 122 that receives an incident reference frequency signal 120 and divider signal 164. Charge Pumps 124 (CPs), biased by a drive voltage 126, are provided to translate the phase difference of the reference signal 120 and the divider signal 164 into a voltage 130 that is filtered by a low pass filter arrangement 132. A tuning voltage 140 is then supplied to a voltage controlled oscillator 150 (VCO) and a voltage controlled oscillator frequency signal 160 generated. As noted above, the divider signal 164 is generated by a divider 162, which is used to control a frequency sweep or chirp of the voltage controlled oscillator frequency signal 160. The divider 162 is often implemented with a sigma-delta to obtain a fractional-N PLL.

The gain of the phase lock loop 110 is a design parameter that is used to optimize the bandwidth, locking time and noise performance of the PLL. For example, both the charge pump gain, K_{D} (PFD/CP gain) and the oscillator gain, Kvco (VCO gain) are parameters that are ideally linear. FIG. 1B shows 168 a typical response 172 of the gain K_{D} 170 as a function of the tuning voltage 140. The response 172 is broadly flat except at low and high tuning voltages.

The response 178, 182 of the gain 180 of the voltage controlled oscillator 150 as a function of the tuning voltage 140 is shown in FIG. 1C. This response, is typically defined by the varactor transfer function, which in embodiments is modelled by a Hyperbolic Tangent function. Hence it is dependent upon the voltage used to tune the PLL, the Vₜᵤₙₑ voltage resulting in a peaked derivative response as shown in 178. As shown, the gain of the voltage controlled oscillator, K_{VCO}, typically has a sharply peaked variation as the tuning voltage is swept from 0 to a maximum drive voltage VDD. In most applications this variation is acceptable, since calibration of the varactor is used to operate the PLL around a mid Vₜᵤₙₑ voltage (VDD/2), which is broadly level for K_{D} and K_{VCO}. The PLL subsequently locks onto this mid tuning voltage which is related to the phase and frequency of the driving signal, as well as the gain from the oscillator. If the PLL is operated outside of this sweet spot frequency errors occurs as the degraded phase noise.

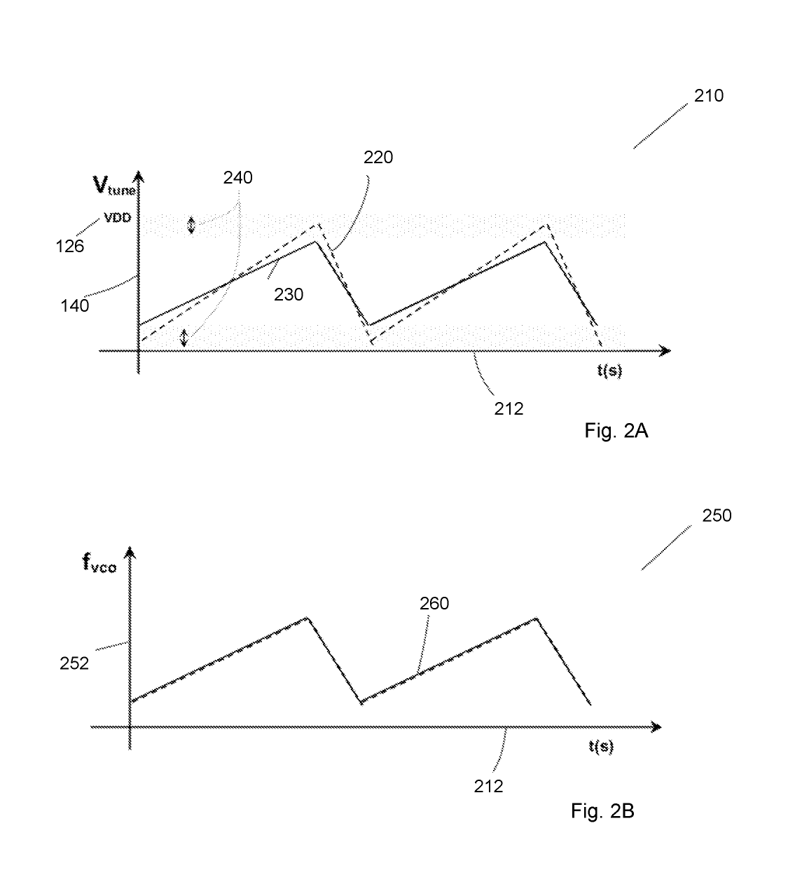

However, not all applications allow a steady input frequency or voltage. In some applications, such as car radar systems the frequency is swept and a chirp generated (by changing the division ratio) from a starting frequency by an amount dependent upon the bandwidth. Such a sweep is shown in FIG. 2A 210 as a function of the tuning voltage and in FIG. 2B 220 as a function of the frequency. In FIG. 2A, the tuning voltage 140 or varactor is swept over almost its full range of voltages (220—dashed line in FIG. 2A) over a period of time 212, minus a small chargepump/VCO headroom 240 above zero voltage and below the drive voltage 126. However, crossing these headroom boundaries 240 results in a large open loop gain variation, large variation in PLL bandwidth, high settling times and also to poor phase noise performance in the system. If the voltage is low, sources are lost and the charge pump gain drops. Accordingly, the systems are overdesigned, resulting in a higher Kvco gain and a reduced Vtune range as the tuning voltage range is swept (idealized overdesigned gain 230—solid line in FIG. 2A).

FIG. 2B shows the variation 250 of the frequency 252 over the period of time 212 by varying the voltage as shown in FIG. 2A for the idealized overdesigned gain 230, which provides frequency response 260.

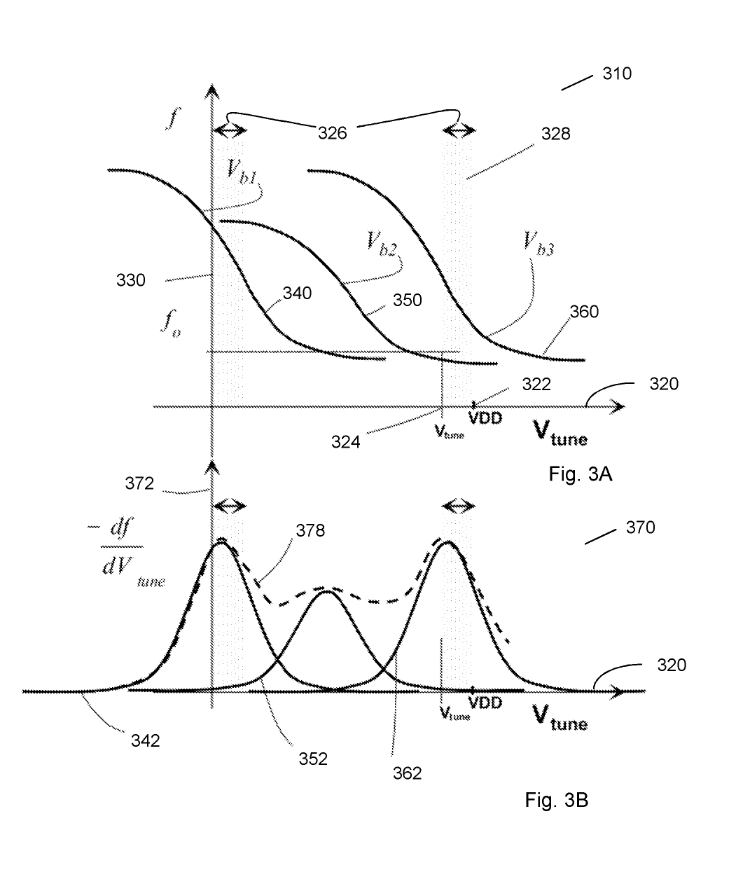

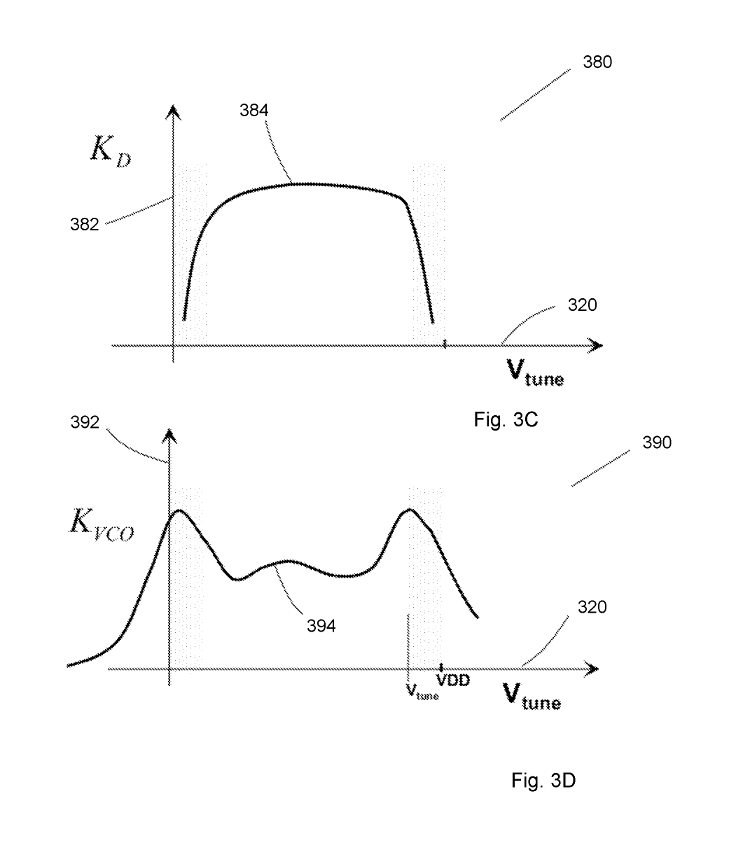

As noted above, the variation of the response of a phase locked loop is at least partially determined by the electrical configuration of components known as varactors. In the present disclosure a number of varactors are employed within a phase locked loop system. FIG. 3a shows 310 how the frequency response 330 of a number of varactors 340, 350, 360 varies as the tuning voltage 320 varies or is swept in a PLL system. As shown, a drive voltage 322 is typically moderated down to a maximum tuning voltage 324. A headroom 326 due mainly to the chargepump is also present. The upper headroom 328 is generally between the ideal maximum tuning voltage 324 and the drive voltage 322.

It can be seen that the frequency response of the varactors at subset ranges of tuning voltages V_{b1}, V_{b2}, V_{b3} can be chosen to provide the frequency response desired. For example, the first varactor 340 is configured to generate a varying capacitance and therefore a varying frequency response over a first subset range of tuning voltages V_{b1} ranging from a negative voltage to a positive voltage broadly centred around zero volts. The second varactor 350 is configured to generate a varying capacitance and therefore a varying frequency response over a second subset range of tuning voltages V_{b2} between zero volts and the tuning or drive voltage 322. Similarly the third varactor 360 is configured to generate a varying capacitance and therefore a varying frequency response over a third subset range of tuning voltages V_{b3} broadly centred around the tuning voltage 324.

A derivative representation 370 of the frequency response 372 of the varactors plotted in FIG. 3a as the voltage 320 varies is shown in FIG. 3b. The first varactor, having a tuning range of V_{b1}, has a derivative frequency response 342 broadly centred around Vₜᵤₙₑ=0. The third varactor, having a tuning range of V_{b3}, has a derivative frequency response 362 centred broadly around the maximum tuning voltage Vₜᵤₙₑ 324, with the second varactor, having tuning range V_{b2}, sitting between. The overall derivative frequency response of all three varactors is curve 378.

Applying the use of several varactors to a phase lock loop circuit such as shown in FIG. 1A allows the gain of the voltage controlled oscillator 150 to be altered to reduce the large variation at high and low tuning voltages as shown in FIG. 1B. FIG. 3C shows 380 how the gain 382 of the phase detector K_{D} varies as the tuning voltage 320 is altered. The response 384 is broadly flat except at high and low tuning voltages. This is similar to the gain characteristics of the phase detector of known phase locked loops as shown in FIG. 1B.

However, for the gain of the voltage controlled oscillator, the use of several varactors provides a greatly altered response as shown 390 in FIG. 3D, in comparison to FIG. 1 C. The response 394 of the gain 392 of the voltage controlled oscillator 150 as the tuning voltage 320 is swept from 0 to a drive voltage is broadly similar to the derivative frequency response shown in FIG. 3b. Instead of the single peak at around half the drive voltage as shown in FIG. 1C, the response 390 has a number of peaks at voltages equal to the maximum differential response of each varactor. In the example shown, three varactors are employed, the first varactor 340 has a maximum derivative frequency response at the drive voltage, the second varactor 350 has a maximum response at half the drive voltage and the third varactor has a maximum response at 0 V. The combined response provides a gain response of the open loop gain of the frequency synthesiser circuit in which the varactors are used with peaks at the same respective voltages as the varactors used, however the overall response is broadly more even with less variation than the single varactor response shown in FIG. 1C.

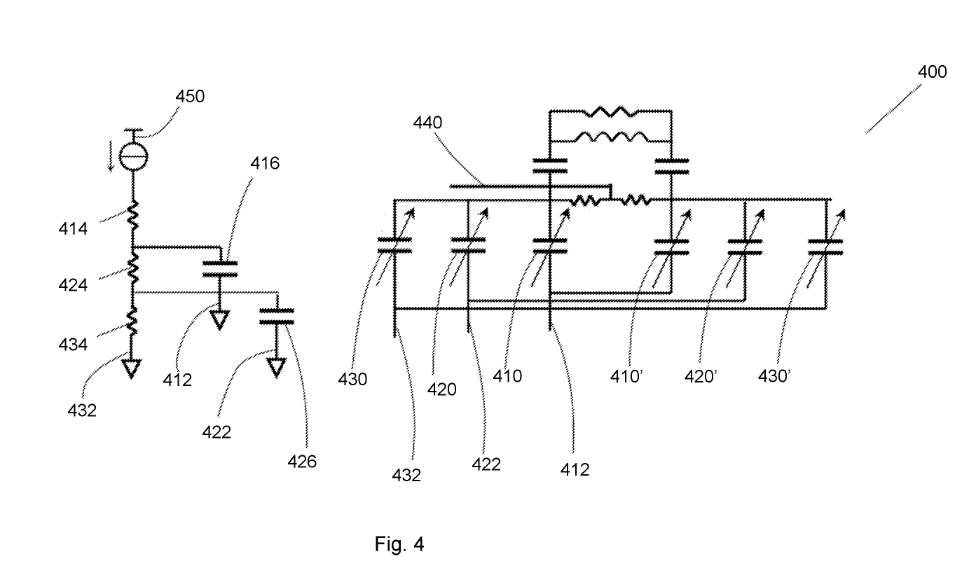

FIG. 4 shows an exemplary system 400 of varactor units used with a voltage controlled oscillator of a PLL according to the present disclosure. In the present example, the voltage controlled oscillator has a first varactor unit comprising a first and second varactor 410, 410′ biased by a drive or bias voltage 412. A second varactor unit is provided, which comprises a first and second varactor 420, 420′ biased by a second bias voltage 422. Additionally a third pair of varactors 430, 430′ are also provided to form a third varactor unit, biased by a third bias voltage 432.

A tuning voltage 440 is supplied to the voltage controlled oscillator, driven by the charge pump 124, which produces a frequency response of the voltage controlled oscillator dependent on the bias of the voltage controlled oscillator and the value of the tuning voltage (as shown in FIG. 2A).

The gain of the voltage controlled oscillator is determined by the varactor units and the inherent gain of the voltage controlled oscillator. Accordingly, by altering the characteristics and/or number of varactor units and/or the bias voltages supplied to the varactor units, the gain of the voltage controlled oscillator can be controlled.

Consequently, the varactor units within the voltage controlled oscillator act to alter the gain of the voltage controlled oscillator, which in turn alters the frequency response of the voltage controlled oscillator with respect to the range of tuning voltages supplied to the voltage controlled oscillator as shown in FIG. 2A. It is therefore possible to smooth out variations in the overall open-loop gain of the PLL and therefore in the frequency response of the voltage controlled oscillator at different applied tuning voltages.

In particular, the varactor units are scaled or sized to alter the voltage controlled oscillator gain that is higher at low and high tuning voltages to compensate for drop-off in the gain of the charge pump. This allows the overall open loop gain of the phase locked loop to remain substantially constant. In other words, by providing a non-linear bias of the voltage controlled oscillator by choosing the number and/or characteristics of the varactors within the voltage controlled oscillator, a linear open loop gain of the phase locked loop can be achieved.

It can be appreciated that more of less varactor units may be employed within the voltage controlled oscillator depending upon the required application. Additionally, although shown as pairs of varactors, each varactor unit may be a single varactor biased by a single bias voltage, a triplet of varactors each biased by a single bias voltage, or 4 or more varactors each biased by a single bias voltage.

Each varactor 410, 420, 430 (and corresponding pair) in the example shown comprises a capacitor. However diodes or other electrical components that have a gain response that varies with frequency may be used as varactors.

The bias voltages are provided from a current source 450 in series with a resistor 414: and in parallel with a capacitor 416 for the first bias voltage 412; in series with a second resistor 424 and in parallel with a second capacitor 426 for the second bias voltage 422; and in series with the second 424 and a third resistor 434 for the third bias voltage 432.

The total capacitance of each varactor shown in FIG. 4 is given by:

$${C}_{va r} = {V}_{va r , m i n} + {C}_{a} \cdot tanh ( \frac{Vg - {V}_{s / d}}{{V}_{nom}} ) ;$$

where Cᵥₐᵣ is the total capacitance of the varactor; C_{var,min} is the natural capacitance of the varactor electrical components; Cₐ is the portion of the varactor capacitance dependent upon voltage, which is dependent on the tan h function; V_{g} is the current gain voltage supplied to the varactor by current that flows into a resistor, which is normally constant; V_{s/d} is the tuning voltage applied to the PLL; and Vₙₒₘ is the nominal voltage of the varactor, typically determined by the process or system use.

It can be appreciated that V_{g} and V_{s/d} can be swapped, resulting in an inverse graph to that shown in FIG. 3b. Consequently, if V_{g} is used as a tuning voltage and V_{s/d} is constant, then the slope of the transfer function of the varactor is positive, whilst its frequency response and slope is negative (the frequency is roughly proportional to the inverse square root of the capacitance of the varactor

Tuning of the varactor units is possible by adding further varactors, altering the varactor components or by altering the bias voltage characteristics. Although shown as three pairs of varactors, any number such as 10 or more pairs may be used, however phase noise considerations provide a notable trade off as the total number of varactors increases.

The phase locked loop 100 comprising the varactors 400 described above may be used to generate a frequency chirp for applications such as sensors. One example may be a sensor for radar systems suitable for use within a car radar system. In such applications, as the tuning voltage is swept, the frequency output of the PLL varies due to the variance in the open loop gain (due to the variance in the voltage controlled oscillator gain caused by the varactors 410, 420, 430).

From reading the present disclosure, other variations and modifications will be apparent to the skilled person. Such variations and modifications may involve equivalent and other features which are already known in the art of varactors and which may be used instead of, or in addition to, features already described herein.

Although the appended claims are directed to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The applicant hereby gives notice that new claims may be formulated to such features and/or combinations of such features during the prosecution of the present application or of any further application derived therefrom.

For the sake of completeness it is also stated that the term “comprising” does not exclude other elements or steps, the term “a” or “an” does not exclude a plurality, a single processor or other unit may fulfill the functions of several means recited in the claims and reference signs in the claims shall not be construed as limiting the scope of the claims.

1. A frequency synthesiser circuit for a radar system, the circuit comprising:
a phase locked loop for providing a frequency chirp at a range of tuning voltages, said phase locked loop comprising:
a phase detector; and
a voltage controlled oscillator and
wherein said phase locked loop has an open loop gain dependent on the tuning voltage and a gain of the voltage controlled oscillator;
a first varactor unit for altering the gain of the voltage controlled oscillator over a first subset range of tuning voltages; and
a second varactor unit for altering the gain of the voltage controlled oscillator over a second subset range of tuning voltages, wherein the second subset range of tuning voltages is higher than the first subset range of tuning voltages;
such that variations in the open loop gain over the first and second subset range of voltages of the range of tuning voltages are compensated for by the varactor units.

2. The circuit of claim 1, wherein the first and second varactor units alter the gain of the voltage controlled oscillator relative to the gain of the charge pump such that the open loop gain is substantially constant.

3. The circuit of claim 1, further comprising a third varactor unit for altering the gain of the voltage controlled oscillator over a third subset range of tuning voltages, wherein the third subset range of tuning voltages is lower than the second subset range of tuning voltages and higher than the first subset range of tuning voltages.

4. The circuit of claim 3, wherein the third varactor alters the gain of the voltage controlled oscillator less than the first or second varactor.

5. The circuit of claim 1, further comprising an nth varactor unit for altering the gain of the voltage controlled oscillator over an nth subset range of tuning voltages of the range of tuning voltages.

6. The circuit of claim 1, wherein each varactor unit comprises a pair of varactors biased by a bias voltage.

7. The circuit of claim 6, wherein the bias voltage is generated by a current and a low pass filter.

8. The circuit of claim 6, wherein the amount of compensation in the open loop gain by the varactor units is dependent upon the capacitance of the varactor unit and the bias voltage of the varactor unit.

9. The circuit of claim 1, wherein the varactor units compensate for variations in the open loop gain at high and low sweeping tune voltages.

10. The circuit of claim 1 wherein the varactor units contain diodes.

11. The circuit of claim 1, wherein the varactor units contain capacitors.

12. The circuit of claim 9, wherein the frequency chirp relates to a distance measurement in a radar system.

13. The circuit of claim 1, wherein a divider is provided and implemented with a sigma-delta to obtain a fractional-N phase locked loop.

14. The circuit of claim 1, wherein the frequency chirp of the phase locked loop is generated by changing a division ratio of a divider and/or by changing a reference frequency signal.

15. A sensor for determining a distance between objects, said sensor comprising a circuit according to claim 1.
